(19) United States
(12) Patent Application Publication
(10) Pub. No.: US 2013/0295363 A1
(43) Pub. Date: Nov. 7, 2013

(54) METAL NITRIDES AND PROCESS FOR PRODUCTION THEREOF

(71) Applicant: MITSUBISHI CHEMICAL CORPORATION, Chiyoda-ku (JP)

(72) Inventor: Hideto TSUJI, Yokohama-shi (JP)

(21) Appl. No.: 13/914,066

(22) Filed: Jun. 10, 2013

Related U.S. Application Data
(63) Continuation of application No. 11/573,412, filed on Feb. 8, 2007.

(30) Foreign Application Priority Data
Aug. 20, 2004 (JP) 2004--240344

(51) Int. Cl. C30B 28/06; C30B 29/40; C09K 11/62

(52) U.S. Cl. CPC C30B 28/06; C09K 11/621; C30B 29/406
USPC 428/219; 423/409

(57) ABSTRACT

A method for producing a metal nitride by employing a container made of a nonoxide material, wherein reaction or adhesion of a raw metal or metal nitride to be formed to the container can be avoided and inclusion of oxygen derived from the material of the container can be prevented; by securing a certain or larger supply amount and a certain or higher flow rate of the nitrogen source gas, the raw metal can be converted into a nitride with an extremely high conversion, and a metal nitride having a small amount of an unreacted raw metal remaining and containing a metal and nitrogen in a stoichiometric constant can be obtained with a high yield; a metal nitride having small amounts of unreacted raw metal remaining and oxygen included can be obtained with a high yield and is very useful as a raw material for bulk crystal growth.

This application is a continuation of U.S. application Ser. No. 11/573,412 filed Feb. 8, 2007, which is a National Stage of PCT/JP2005/014957 filed Aug. 16, 2005, both of which are incorporated herein by reference. This application also claims the benefit of JP 2004-240344 filed Aug. 20, 2004.

### TECHNICAL FIELD

The present invention relates to a metal nitride. Particularly, it relates to a nitride of a metal element of Group 13 of the Periodic Table represented by gallium nitride and a method for producing a metal nitride.

### BACKGROUND ART

Gallium nitride (GaN) is useful as a substance applicable to an electron device such as a light emitting diode or a laser diode. As a method for producing gallium nitride crystals, it is most common to carry out vapor phase epitaxial growth on a substrate of e.g. sapphire or silicon carbide by MOCVD (Metal-Organic Chemical Vapor Deposition). However, this method employs heteroepitaxial growth with differences in lattice constant and coefficient of thermal expansion between the substrate and gallium nitride, and thereby has such problems that gallium nitride to be obtained is likely to have lattice defects and that it is difficult to obtain high quality applicable to a blue laser or the like.

Accordingly, in recent years, establishment of technique to produce gallium nitride bulk single crystals to be used as a substrate for homoepitaxial growth has been strongly desired. As one of new methods for producing gallium nitride bulk single crystals, a solution growth method for a metal nitride using supercritical ammonia or an alkali metal flux as a solvent has been proposed. In order to obtain high quality gallium nitride bulk single crystals, it is also required to produce as a raw material high quality polycrystals of gallium nitride in which the amount of impurities is small and the ratio of gallium to nitrogen is more stoichiometric at a low cost.

With respect to polycrystals (powder) of gallium nitride, a production method from gallium metal and a production method from gallium oxide have been mainly known. In addition, production methods from various gallium salts or organic gallium compounds have been reported, but they have no advantage in view of the conversion, the recovery percentage, purity of gallium nitride to be obtained, cost, etc. In a case of producing gallium nitride from gallium metal or gallium oxide using an ammonia gas, it is very difficult to obtain gallium nitride in which the amount of impurities particularly oxygen is small and the ratio of gallium to nitrogen is stoichiometric. Gallium nitride does not intrinsically absorb visible light and is colorless, but if oxygen is contained in a large amount, an impurity level is formed in a band gap, whereby the resulting gallium nitride will be brownish to yellowish gallium nitride. In a case of producing gallium nitride using gallium metal as a raw material by means of a reaction with an ammonia gas, the resulting gallium nitride will not contain oxygen derived from the oxide as in the case of using gallium oxide as a raw material. However, if unreacted raw gallium metal remains after the reaction, the resulting gallium nitride is likely to contain oxygen by oxidation of the remaining gallium metal. Further, if unreacted raw gallium metal remains in a large amount, the resulting gallium nitride will be grayish to blackish gallium nitride. When such gallium nitride is used as a material for production of bulk single crystals, a step of removing such impurities in the production process will be required, otherwise, problems such as dislocation or defect may occur. Accordingly, if oxygen or unreacted raw metal remains in gallium nitride, it is required to remove them as far as possible.

In Non-Patent Document 1, gallium metal is reacted with ammonia gas on a quartz or alumina boat to obtain dark gray h-GaN (hexagonal gallium nitride). However, the conversion is at most 50%, and a large amount of unreacted raw gallium metal remains in the product, and accordingly, washing has to be carried out with e.g. a mixed solution of hydrofluoric acid and nitric acid to remove metallic gallium from the product, such being poor in efficiency. Likewise, in Patent Document 1, an ammonia gas is bubbled into a gallium metal melt put in a quartz crucible to obtain h-GaN in the form covered with gallium metal, and accordingly, in order to obtain h-GaN, a step of washing the gallium metal portion with e.g. hydrochloric acid or hydrogen peroxide is required. Further, the remaining gallium metal can not sufficiently be removed by washing with e.g. a general acid, and in the case of the latter, gallium in an amount of 2 wt % is contained and remains in h-GaN for example.

On the other hand, a method of vaporizing gallium metal by nitrogen and reacting the obtained gallium metal vapor with an ammonia gas in a gas phase to obtain dark gray h-GaN has been proposed (Non-Patent Document 2). Further, a method of reacting an ammonia gas with a gallium metal vapor in a gas phase, transporting the formed crystal nuclei of gallium nitride and then reacting gallium chloride with an ammonia gas on the crystal nuclei to obtain h-GaN in a quartz tube vessel has also been proposed (Patent Document 2). However, in such methods, the yield is so low as at most 30%, and the formed h-GaN non-selectively forms and adheres on the vessel other than a container in which the raw material is put, and thus it is not easy to recover the formed product.

Further, inclusion of oxygen, derived from the material of a reactor with which the obtained h-GaN is in contact, or in a post-treatment step such as washing, is inevitable in gallium nitride obtained by a conventional method as shown in Table 1 of Non-Patent Document 3, and accordingly oxygen is contained in an amount of 0.08 wt % even as an analyzed value with a minimum amount of oxygen included. Further, in such a case, a considerable amount of metallic components including Ga is contained, thus decreasing purity of h-GaN.

Accordingly, the nitride obtained by the above-described methods is not necessarily sufficient in view of crystallinity and inclusion of impurities, and it has been desired to develop an efficient process for producing a nitride having high crystallinity and having a higher purity.

Patent Document 1: Japanese Patent No. 3533938

Patent Document 2: JP-A-2003-63810

Non-Patent Document 1: J. Crystal Growth Vol. 211 (2000) 184p J. Kumar et al.

Non-Patent Document 2: Jpn. J. Appl. Phys. Part 2 40 (2001) L242p K. Hara et al.

Non-Patent Document 3: J. Phys. Chem. B Vol. 104 (2000) 4060p M. R. Ranade et al.

### DISCLOSURE OF THE INVENTION

Problems that the Invention is to Solve

The present invention has been made to solve the above problems, and it is an object of the present invention to provide a high quality metal nitride having high crystallinity and containing a small amount of impurities. Further, another object of the present invention is to provide a method for producing a metal nitride containing a small amount of impurities, particularly to provide a method of nitriding a raw metal with high conversion, since in production process, great effort is required to remove a remaining unreacted raw metal.

Means of Solving the Problems

The present inventor has conducted extensive studies and as a result, succeeded in providing a high quality metal nitride having high crystallinity and containing a small amount of impurities, which has not been obtained by a conventional method, by employing a specific production method.

Further, he has found that in a method of nitriding a raw metal with a nitrogen source gas, the material of a container with which the raw metal and a metal nitride to be formed are in contact, affects the quality of the metal nitride to be formed, particularly inclusion of oxygen, more than expected, and achieved the present invention. Namely, he has accomplished the above objects by using a nonoxide as the container material which is a nitride such as boron nitride or a carbon material such s as graphite, while avoiding use of a quartz or an oxide such as alumina which is commonly used as the material of the container, to obtain a metal nitride containing a small amount of impurities.

Further, he has found that high purity h-GaN can be obtained with an extremely high conversion by a method of nitriding a raw metal with a nitrogen source gas wherein the nitrogen source gas is supplied in a certain or larger amount at a certain or higher flow rate at a predetermined reaction temperature, when the raw metal is put in a container such as a crucible or a boat and the raw metal is converted into a nitride in or on the container, and achieved the present invention. Namely, according to the present invention, the above objects can be accomplished by using a container made of a nonoxide material, supplying a nitrogen source gas in a certain amount or more at a certain or larger flow rate, and reacting a raw metal with a nitrogen source gas at a high temperature to obtain a metal nitride with a conversion and a yield of at least 90%.

The present invention provide the following: (1) A metal nitride containing a metal element of Group 13 of the Periodic Table, characterized by having an oxygen content of less than 0.07 wt %.

(2) The metal nitride according to the above (1), characterized by having a content of a zero valent metallic element of less than 5 wt %.

(3) The metal nitride according to the above (1) or (2), characterized by containing nitrogen in an amount of at least 47 atomic %.

(4) A metal nitride characterized in that the color tone by a color difference meter is such that L is at least 60, “a” is at least −10 and at most 10, and “b” is at least −20 and at most 10.

(5) The metal nitride according to any one of the above (1) to (4), characterized in that the maximum length of primary particles in a major axis direction is at least 0.05 μm and at most 1 mm.

(6) The metal nitride according to any one of the above (1) to (5), characterized by having a specific surface area of at least 0.02 m²/g and at most 2 m²/g.

(7) The metal nitride according to any one of the above (1) to (6), characterized in that the metal element of Group 13 of the Periodic Table is gallium.

(8) A metal nitride molded product, which is pellets or a block obtained by molding the metal nitride as defined in any one of the above (1) to (7).

(9) A method for producing a metal nitride, which comprises putting a raw metal in a container and reacting the raw metal with a nitrogen source to obtain a metal nitride, characterized in that an inner surface of the container is made of at least a nonoxide as the main component, and that the method has a step of supplying a nitrogen source gas so that it is in contact with a surface of the raw metal in a supply amount by volume per second of at least 1.5 times the volume of the raw metal, or supplying it at a gas flow rate of at least 0.1 cm/s on the raw metal, at a reaction temperature of at least 700° C. and at most 1,200° C.

(10) The method for producing a metal nitride according to the above (9), characterized in that the raw metal is converted into a nitride in an amount of at least 90%.

(11) The method for producing a metal nitride according to the above (9) or (10), characterized in that the raw metal is gallium.

(12) A method for producing metal nitride bulk crystals, characterized in that the metal nitride or the metal nitride molded product as defined in any one of the above (1) to (8) is used.

Effects of the Invention

According to the present invention, a metal nitride containing a small amount of impurity oxygen can be provided by a specific method for producing a metal nitride. According to the present invention, in a method of making a surface of a raw metal and a nitrogen source gas be in contact and react with each other in or on a container, a certain or shorter contact time with a nitrogen source gas i.e. a certain or larger supply amount and a certain or higher flow rate of a nitrogen source gas are secured, whereby remaining of an unreacted raw metal is avoided as far as possible, and further, a nonoxide material such as BN or graphite is used for a container with which the raw metal and a metal nitride to be formed are in contact, whereby inclusion of oxygen is thoroughly eliminated, and production of a metal nitride containing a metal and nitrogen in a stoichiometric constant ratio with high yield becomes easy. Further, by using a container made of a nonoxide material, adhesion of a metal nitride to be formed to the container can be avoided and an extremely high yield can be achieved.

Best Mode for Carrying out the Invention

Now, the metal nitride and the method for producing it of the present invention will be explained in further detail below. The following explanation of the constituents is one example of the embodiments of the present invention, and the present invention is by no means restricted to such embodiments.

Metal Nitride

The type of the metal nitride of the present invention is not particularly limited, and preferred is a nitride containing a metal element of Group 13 of the Periodic Table, such as Al, Ga or In. For example, a nitride of a simple metal such as GaN or AlN or a nitride of an alloy such as InGaN or AlGaN is preferred, and among them, a nitride of a simple metal is preferred, and particularly gallium nitride is preferred.

The metal nitride of the present invention is characterized in that the amount of oxygen as an impurity included is reduced to the minimum. The inclusion form of oxygen may, for example, be inclusion of impurity oxygen to the crystal lattice of the metal nitride, inclusion of oxygen or moisture which is adsorbed on the surface of the metal nitride, or inclusion of an oxide or a hydroxide including an amorphous form. The amount of such oxygen included can easily be measured by an oxygen and nitrogen analyzer. The amount of oxygen included is less than 0.07 wt %, preferably less than 0.06 wt %, particularly preferably less than 0.05 wt %.

Further, the metal nitride of the present invention is characterized in that inclusion or attachment of a zero valent metallic element is reduced to the minimum. The zero valent metallic element means a metal which may cause a decrease in purity of the formed metal nitride, and includes a simple metal or a compound of the raw metal itself remaining in the process for producing the metal nitride. The remaining amount of such a zero valent metal can be easily measured quantitatively by ICP elemental analysis of the zero valent metal element extracted from the product with an acid. The amount of the zero valent metallic element included or attached is less than 5 wt %, preferably less than 2 wt %, more preferably less than 1 wt %, particularly preferably less than 0.5 wt %. In such a manner, in the present invention, the amount of the zero valent metallic element included or attached is reduced to the minimum, whereby the obtained metal nitride can be used as a high purity metal nitride as it is without carrying out a washing step using an acid such as hydrochloric acid, hydrogen lo peroxide or the like.

Further, the metal nitride of the present invention is preferably a metal nitride containing a metal and nitrogen in amounts close to be stoichiometric. The amount of nitrogen contained can be measured by using the above-mentioned oxygen and nitrogen analyzer. The amount of nitrogen contained is preferably at least 47 atomic %, more preferably at least 49 atomic %.

Further, the metal nitride of the present invention has its characteristic also in view of its color tone, due to a small amount of the zero valent metallic element included or attached, originating from an unreacted raw metal or the like, and shows the intrinsic color as expected from the band gap. Namely, with reference to gallium nitride as an example, even in the form of a powder obtained by e.g. grinding, the gallium nitride is closer to transparent and colorless, or looks almost white due to scattering. The color tone of the metal nitride can be measured, for example, by means of a color difference meter after grinding into a powder having a particle size of about 0.5 μm. Usually, L representing the lightness is at least 60, “a” representing the red-green coordinate is at least −10 and at most 10, and “b” representing the yellow-blue coordinate is at least −20 and at most 10, and preferably L is at least 70, “a” is at least −5 and at most 5, and “b” is at least −10 and at most 5.

The metal nitride of the present invention is useful also as a raw material for bulk single crystal growth. As a growth method to obtain nitride bulk single crystals, a known method, such as a solution growth method using a supercritical ammonia solvent or an alkali metal flux, or a sublimation method or a melt growth method can be applied. As the case requires, a seed crystal or a substrate may be utilized to carry out homo- or heteroepitaxial growth.

The metal nitride of the present invention contains an extremely small amount of a remaining zero valent metal, and accordingly, it can be used as a material for bulk single crystal growth as it is without a removal step by washing with an acid such as hydrochloric acid or a hydrogen peroxide solution. Further, it has a low impurity oxide concentration, it contains a metal and nitrogen in a substantially stoichiometric constant ratio, and bulk single crystals to be obtained from it has excellent characteristics in view of low density of lattice defect, and dislocation, etc.

The metal nitride of the present invention may be molded preferably into pellets or a block as the case requires. Further, the bulk nitride single crystals obtained by crystal growth using the metal nitride of the present invention as a raw material, may be washed with hydrochloric acid (HCl), nitric acid (HNO₃) or the like, sliced parallel to a specific crystal index plane, and as the case requires, subjected to etching or polishing to obtain a self-supporting nitride single crystal substrate. The obtained nitride single crystal substrate contains a small amount of impurities and has high crystallinity, and it can thereby be used as a substrate, is particularly a substrate for homoepitaxial growth, in production of various devices by means of VPE and/or MOCVD.

Method for Producing Metal Nitride

Example of Nitridation Apparatus and Raw Material

Now, a preferred method for producing the metal nitride of the present invention will be explained below. The metal nitride having specific physical properties as defined by the present invention can be obtained as a metal nitride formed by introducing a nitrogen source gas such as an ammonia gas in contact with a surface of a raw metal put in a container made of a nonoxide material at a certain or higher supply and flow rate, as a typical production method.

As the materials, a raw metal and a nitrogen source are used, and in usual, it is preferable to use the above-mentioned metal (zero valent metal) and a nitrogen source gas. As the nitrogen source gas, an ammonia gas, a nitrogen gas, a kind of hydrazine such as an alkylhydrazine or an amine may, for example, be used.

It is essential in the present invention that the metal and the nitrogen source gas as raw materials are lo brought into contact with each other. As a particularly preferred production method, a container in which a high purity metal as a raw material is put is installed in a vessel, a nitrogen source gas is made to flow through the vessel, whereby the raw metal is converted into a metal nitride in or on the container by nitridation based on a reaction of the raw metal with the nitrogen source gas which is in contact with a surface of the raw metal. The present invention is characterized in that the container with which the raw metal and a metal nitride to be formed are in direct contact is made of a nonoxide material.

Usually, a quartz container or an alumina container is used for such nitridation of a metal. When such an oxide material is used as the container, an unfavorable oxygen component is likely to be included in the metal nitride to be formed due to direct contact between the oxide material and the raw metal or the metal nitride to be formed. However, when a container made of a nonoxide material such as BN or graphite as examples of the material of the container in the present invention is used, a reaction of the metal or the molten metal put as the raw material in the container is less likely to take place, and inclusion of oxygen in the metal nitride to be formed can be prevented. Further, the container made of a nonoxide material of the present invention is chemically inactive, whereby adhesion of the metal nitride to be formed to the container can be prevented and accordingly, an extremely high recovery can be achieved.

As the nonoxide used as the material of the container of the present invention, SiC, Si₃N₄, BN, carbon or graphite, preferably BN or graphite, particularly preferably pBN (pyrolytic boron nitride) may be used. pBN is highly durable, and its inclusion into the metal nitride to be formed will not be problematic, and thus it is preferred.

Further, such a nonoxide material may be prepared or coated on the surface of the container with which the raw metal or the metal nitride to be formed is in direct contact. For example, a kind of carbon paper or sheet is preferably put on the surface of the container.

It is preferred that the container of the present invention in which the raw metal is put is installed in a vessel through which a gas can flow and then nitridation is carried out. It is important to secure air tightness sufficiently for the entire gas flow path including the vessel in view of safety and increase in purity of the metal nitride to be obtained. The material of the vessel is not particularly limited, ceramics such as BN, quartz or alumina with heat resistance even at a high temperature around 1,000° C. are preferably used, for a portion of the vessel to be exposed to high temperature by a heater. The vessel may be made of an oxide, if it is not in contact with the raw metal or the metal nitride to be formed, as different from the above-mentioned container. Further, the shape of the vessel is not particularly limited, but a vertical or horizontal tubular vessel is suitably used so that the gas efficiently flows through it.

The shape of the container is not particularly limited, and preferred is a shape with which the raw metal put in the container is in sufficient contact with the flowing gas. In a case where the container has a shape having a bottom and a side wall, such as a crucible or a boat, the ratio of the area of the wall to the area of the bottom is usually at most 10, preferably at most 5, more preferably at most 3. Further, a splitted tubular shape or a tubular shape, or ball shape may also be suitably used. Further, with respect to putting of the raw metal in the container, the amount and the condition are preferably such that the raw metal is in sufficient contact with the flowing gas. Particularly in a case where the raw metal is melted at the nitridation temperature or lower, the raw metal is preferably put so that the volume ratio of the raw metal to the volume of the container is at most 0.6, preferably at most 0.3, particularly preferably at most 0.1. Further, in a case where the raw metal is melted and becomes a liquid, the raw metal is preferably put so that the ratio of the area of the bottom and wall of the container at a portion where the raw metal is in contact with the container, to the total area of the bottom and wall of the container, is at most 0.6, preferably at most 0.3, particularly preferably at most 0.1. Within this range, escape of the nitride to be formed or the raw metal from the container can be prevented, and the yield of the nitride to be formed can be increased. In the case where the container has a tubular shape, it may have such a structure that an ammonia gas is made to flow through the container itself and the container functions also as a vessel. Otherwise, the container may be rotated so that the ammonia gas is uniformly in contact with the raw metal. The thickness of a portion of the nonoxide material where the container is in direct contact with the raw metal or the metal nitride to be formed, such as the bottom or the side wall of the container, is not particularly limited, and it is usually at least 0.05 mm and at most 10 mm, preferably at least 0.1 mm and at most 5 mm. The thickness of the vessel is usually at least 0.01 mm and at most 10 mm, preferably at least 0.2 mm and at most 5 mm, particularly preferably at least 0.05 mm and at most 3 mm. However, the thickness is not limited thereto within a range not to exceed the scope of the present invention.

When the raw metal is put in the container, or when the container put the raw metal in is installed into the vessel, the operation is carried out preferably in an inert gas atmosphere so as to avoid inclusion of oxygen into the system. It is preferably carried out to install a plurality of containers in one vessel or to install containers in a multistage manner by using a stand or holder made of a heat resistant material such as quartz. In a case where the container is likely to absorb or adsorb oxygen or moisture, it is preferably treated at high temperature in hydrogen or in an inert gas by using the above vessel or another vessel, or evacuated to be inactivated or dried.

As the raw metal for the metal nitride, it is usually preferred to employ a simple metal. In production of a high purity metal nitride, it is desired to use a high purity simple metal substance, and usually at least 5 N, preferably at least 6 N, particularly preferably at least 7N is employed. Further, the amount of oxygen contained in the raw simple metal is usually less than 0.1 wt %. Further, in order to avoid inclusion of oxygen, handling in an inert gas is preferred. The shape of the raw metal is not particularly limited, but the raw metal is put in the container preferably in the form of particles having a diameter of at least 1 mm with a small surface area rather than a powder, preferably in the form of a bar or an ingot. The reason is to prevent inclusion of oxygen by oxidation on the surface. In a case of a metal having a low melting point such as metal gallium, it may be charged in a liquid form.

In the present invention, usually the raw metal is put in a container made of a nonoxide material and then the container is installed into a vessel. In a case where the raw metal is likely to be oxidized or absorb moisture, it is preferred to sufficiently increase purity of the raw metal by carrying out e.g. heating in a vacuum or reduction of the raw metal put in the container by using another apparatus before the installation of the container in the vessel. Further, in such a case, installation into the vessel is more preferably carried out quickly in an atmosphere from which oxygen and moisture are removed as far as possible. For example, the interior of the vessel is sufficiently replaced with an inert gas in a tank or in a room filled with an inert gas, and then the raw metal is introduced, and the container containing the raw metal is installed to the vessel, and then the vessel is sealed. Further, the vessel may be preliminarily arranged so that it can be sealed by a screw cap employing a packing or the like in combination, or the vessel may be sealed by a flange or the like.

The container in which the raw metal is put is usually placed at a vessel position where the temperature goes up to top during heating. Further, it may be s intentionally placed at a position close to an ammonia gas nozzle so that the ammonia gas to be a nitrogen source is effectively in contact with the raw metal. Further, in order to control diffusion or mixing of the gas, uniformity of the flow, etc., an obstacle such as a lo baffle may be provided in the flow path. Also a barrier to prevent diffusion of heat may be provided.

The entire vessel and the plumbing used in the present invention may optionally be inactivated. For example, after the container in which the raw metal is is put is installed, the entire vessel and the plumbing may be evacuated in a high temperature via a hose tube and a valve, or they may be heated to a high temperature while making an inert gas flow therethrough. Further, after the container having a raw metal put therein is installed, the vessel is heated to a high temperature while a reductive gas is made to flow through the vessel to reduce the material and thereby to further increase the purity, or a substance which has a role as a scavenger selectively absorbing oxygen and moisture or removing them by reaction (for example, a metal piece of titanium, tantalum or the like) may be provided in the vessel.

Example of Nitridation Operation

As one example of a metal nitride formation reaction of the present invention, nitridation with an ammonia gas will be explained below. The following is one example of such a method, and the present invention is by no means restricted to such a method.

First, prior to nitridation by an ammonia gas, an inert gas is made to flow into a vessel having a container installed therein via a pipe and a valve which is able to seal the vessel, to sufficiently replace the interior of the vessel with an inert gas. Further, an ammonia gas to be a nitrogen source is introduced to the vessel via a pipe and a valve which is able to seal the vessel. The ammonia gas is introduced to the vessel via the pipe and the valve from a tank without being in contact with the ambient air. It is preferred to introduce a preliminarily determined amount of the ammonia gas by providing a flow amount control apparatus on the way to the vessel. The ammonia gas has high affinity with water and it is thereby likely to introduce oxygen derived from water into the vessel when the ammonia gas is introduced to the vessel, which may cause an increase in the amount of oxygen included in the metal nitride to be formed, and thus lead to deterioration of crystallinity of the metal nitride. Accordingly, it is desired to reduce the amount of water and oxygen contained in the ammonia gas to be introduced to the vessel as far as possible. The concentration of water and oxygen contained in the ammonia gas is at most 1,000 ppm, and it is more preferably at most 100 ppm, particularly preferably at most 10 ppm.

Further, an ammonia gas used industrially usually contains impurities such as a hydrocarbon and NOx in addition to water and oxygen in many cases. Accordingly, it is possible to introduce a high pure ammonia gas purified by distillation or purified by means of a lo purification apparatus utilizing an adsorbent, an alkali metal or the like. In order to produce a high purity metal nitride, the purity of the ammonia gas to be introduced to the vessel is preferably high, and usually 5 N, preferably 6N or higher ammonia gas is suitably used. Further, the inert gas to be used also preferably contains oxygen and moisture as little as possible. The concentration of water and oxygen in the inert gas to be used is at most 100 ppm, preferably at most 10 ppm. It is also preferred to use a high pure inert gas purified by means of a purification apparatus utilizing an adsorbent, a getter or the like.

The interior of the vessel in which the container containing the raw metal is placed is sufficiently replaced with the inert gas, and then the interior of the vessel is heated by a preliminarily equipped heater. The timing of introduction of the ammonia gas is not particularly limited, but the ammonia gas is introduced preferably at a temperature at which the raw metal is melted or higher. It is usually at least room temperature, more preferably at least 300° C., furthermore preferably at least 500° C., particularly preferably at least 700° C. It is preferred to heat the vessel and increase the temperature while making the inert gas flow until introduction of the ammonia gas. As the nitridation of a metal proceeds usually at a temperature of at least 700° C., waste of the ammonia gas can be cut lo down by introducing the ammonia gas after the raw metal reaches a temperature of at least 700° C. Further, in a case where the problem of heat formation by the reaction raises due to rapid progress of the nitridation, it is suitable to begin to introduce the ammonia gas in a very small supply amount and gradually increase the supply amount, or to increase the temperature stepwisely or to introduce the ammonia gas stepwisely. Further, it is also suitable to introduce the ammonia gas dividedly using more than one tube or to introduce the inert gas and the ammonia gas individually. This is particularly effective when a plurality of containers are arranged or placed in a multistage manner.

The nitridation is carried out at a predetermined reaction temperature, and the reaction temperature may optionally be selected depending upon the type of the raw metal. It is at least 700° C. and at most 1,200° C., preferably at least 800° C. and at most 1,150° C., particularly preferably at least 900° C. and at most 1,100° C. The reaction temperature is measured by means of a thermocouple provided to be in contact with the outer surface of the vessel. The temperature s distribution in the vessel may vary depending upon the shape of the vessel, the shape of the heater, their positional relation, and heating or heat insulation, but by inserting a thermocouple to e.g. a sheath tube opened from the outer surface of the vessel into the inside direction, the temperature distribution into the vessel inside direction can be estimated or extrapolated to estimate the temperature of the container portion, thereby to determine the reaction temperature.

The temperature-raising rate to the above is predetermined reaction temperature is not particularly limited, and it is preferably at least 1° C./min, more preferably at least 3° C./min, particularly preferably at least 5° C./min. If the temperature-raising rate to the predetermined reaction temperature is too low, nitridation may proceed only on the surface of the raw metal to form a nitride film before nitridation takes place at the inner portion, thus preventing nitridation in the inner portion. As the case requires, it is suitable to increase the temperature stepwisely, or to vary the temperature-increasing rate in a temperature range. Further, it is also possible to heat the vessel with a partial difference in temperature, or to heat it while partially cooling it. The reaction time at the above predetermined reaction temperature is usually at least 1 minute and at most 24 hours, preferably at least 5 minutes and at most 12 hours, particularly preferably at least 10 minutes and at most 6 hours. During the reaction, the reaction temperature may be constant, or the temperature may be gradually increased or lowered in a preferred temperature range, or such an operation may be repeated. It is also suitable to initiate the reaction at a high temperature and then lower the temperature to complete the reaction.

Example of Supply of Nitrogen Source Gas

Now, the supply amount of the nitrogen source gas during the metal nitride formation reaction of the present invention will be explained with reference to the supply amount of gas when an ammonia gas is used as the nitrogen source gas. The following is one example of such a method, and the present invention is by no means restricted to such a method. The supply amount and the flow rate of the ammonia gas in the temperature-increasing step until the temperature reaches the reaction temperature and at the reaction temperature are one of the important condition factors to obtain a high purity nitride with a high yield. For example, if the supply amount of the ammonia gas is insufficient, an unreacted raw metal remains. Further, in a case of a metal with a high vapor pressure, if the supply amount of the ammonia gas is not appropriate, the raw metal may volatilize and escape from the container before progress of the nitridation, whereby a metal nitride to be formed clung to the bottom or wall of the vessel, and thus recovery becomes very difficult and the yield decreases.

Under these circumstances, the present invention is characterized in that the volume of the ammonia gas in standard temperature and pressure (STP) supplied per second is at least 1.5 times the total volume of the raw metal, at least once at a temperature of at least 700° C. including the temperature-increasing step. The volume of the ammonia gas in standard temperature and pressure (STP) supplied per second is preferably at least twice, particularly preferably at least 4 times, the total volume of the raw metal. Further, the time during which the ammonia gas is made to flow in such a supply amount is at least 1 minute, preferably at least 5 minutes, particularly preferably at least 10 minutes. Further, not only the supply amount of the ammonia gas but also its flow rate is an important factor in the nitridation. This is because in a case where the ammonia gas passes through the interior of the vessel including the container at a high temperature, the dissociation of ammonia gas into nitrogen and hydrogen which relates to not only the supply amount but also the flow rate contributes to the nitridation.

The present invention is characterized in that the ammonia gas is supplied at a gas flow rate of at least 0.1 cm/s in the vicinity of the portion on the raw metal, at least once at a temperature of at least 700° C. including the temperature-increasing step. The flow rate of the ammonia gas is preferably at least 0.2 cm/s, particularly preferably at least 0.4 cm/s. Further, the time during which the ammonia gas is made to flow in such a flow rate is at least 1 minute, preferably at least 5 minutes, particularly preferably at least 10 minutes.

In addition, in the present invention, the nitridation of the raw metal proceeds by contact of the raw metal with the ammonia gas, and accordingly, it is preferred that the area of the raw metal which can be in contact with the ammonia gas is large. Particularly when the raw metal is melted below the temperature at which the nitridation proceeds, the raw metal is put so that the area per unit weight of the raw metal which can be exposed to the ammonia gas is at least 0.5 cm²/g, preferably at least 0.75 cm²/g, furthermore preferably at least 0.9 cm²/g, particularly preferably 1 cm²/g. Further, in order that the raw metal is sufficiently converted into a metal nitride, such a device is suitable that the flow rate of the ammonia gas is made high for a deep container and the flow rate is made low for a shallow container, in a case of using containers having the same volume.

The pressure in the vessel during the nitridation is not particularly limited, and it is usually at least 1 kPa and at most 10 MPa, preferably at least 100 kPa and at most 1 MPa.

After the raw metal is converted into a metal nitride, the temperature in the vessel is lowered. The temperature-lowering rate is not particularly limited, and it is usually at least 1° C./min and at most 10° C./min, preferably at least 2° C./min and at most 5° C./min. The lo method of lowering the temperature is not particularly limited. Heating by the heater is stopped, and the vessel containing the container may be left in the heater to cool, or the vessel containing the container may be taken out from the heater and air-cooled. As the case requires, the vessel may be left to cool by using a coolant. It is effective to make the ammonia gas flow also in the temperature-lowering step so as to suppress decomposition of the formed metal nitride. The ammonia is supplied until the temperature in the vessel is decreased to 900° C. at highest, preferably 700° C., more preferably 500° C., particularly preferably 300° C. On this occasion, the volume of the ammonia gas supplied per second is preferably at least 0.2 time the total volume of the raw metal. Then, the temperature is further lowered while making an inert gas flow, and after the temperature at the outer surface of the vessel or the estimated temperature at the container portion reaches a predetermined temperature or lower, the vessel is opened. The predetermined temperature is not particularly limited, and it is usually at most 200° C., preferably at most 100° C.

According to the production method of the present invention, the raw metal is converted into a metal nitride with a high proportion, whereby the vessel is opened and the metal nitride is taken out together with the container, and the formed metal nitride can be lo recovered from the container. On this occasion, the container is taken out preferably in an inert gas atmosphere so that the obtained metal nitride will not adsorb moisture or oxygen.

The container after recovering the formed metal nitride can be reused after cleaned. As the case requires, it can be cleaned by using an acid such as hydrochloric acid or a hydrogen peroxide solution. Further, the vessel may also be similarly cleaned and reused. Further, the vessel may be cleaned and dried at high temperature while making an inert gas, a reducing gas or a hydrochloric acid gas flow through the vessel or evacuating it. On this occasion, the empty container may be disposed in the vessel to clean and dry the container at the same time.

According to the production method of the present invention, a metal nitride can be obtained with an extremely high yield. For example, by securing sufficient supply amount and flow rate of the ammonia gas, the raw metal can be converted into a metal nitride with a high conversion without escape of the raw metal or the formed metal nitride from the container. Further, by using a nonoxide for the material of the container, reaction or adhesion of the raw metal or the formed metal nitride with the container can be avoided, and a high yield can be achieved. In a case where the obtained metal nitride expands by volume and is in a form of a cake, it may be ground and sieved to obtain a powder.

Such treatment and storage are carried out preferably in an inert gas atmosphere so that the obtained metal nitride will not adsorb moisture and oxygen.

Properties of Metal Nitride and Measurement Thereof

The metal nitride obtained by the method of the present invention, such as gallium nitride, is usually in the form of polycrystals. The obtained metal nitride has high crystallinity, and the half width of the peak of (101) which appears around 2θof 37° in powder X-ray diffraction is usually at most 0.2°, preferably at most 0.18°, particularly preferably at most 0.17°. The metal nitride obtained by the method of the present invention comprises, as observed by a scanning electron microscope, needle, column or prism crystals having a primary particle size of from 0.1 μm to several tens μm. The maximum length of the primary particles in a major axis direction is usually at least 0.05 μm and at most 1 mm, preferably at least 0.1 μm and at most 500 μm, more preferably at least 0.2 μm and at most 200 μm, particularly preferably at least 0.5 μm and at most 100 μm. Further, with respect to the specific surface area, it is preferable that the specific surface area of the obtained metal nitride is appropriately small with a view to controlling the dissolution rate, considering one purpose of use as a raw material for production of bulk nitride single crystals by a solution growth method. Further, it is preferably small also to prevent inclusion of impurities by e.g. adsorption of impurities.

The specific surface area of the metal nitride obtained by the method of the present invention is small and it is usually at least 0.02 m²/g and at most 2 m²/g, is preferably at least 0.05 m²/g and at most 1 m²/g, particularly preferably at least 0.1 m²/g and at most 0.5 m²/g. The obtained metal nitride is completely decomposed and dissolved and quantitatively analyzed by means of an ICP elemental analyzer, whereupon the amount of each of the metal elements as impurities is at most 20 μg per gram of gallium nitride, and the obtained metal nitride has an extremely high purity. Further, the amount of impurities for a typical non-metal element such as Si or B, as quantitatively analyzed by an ICP elemental analyzer, is at most 100 μg per gram of gallium nitride, and the amount of carbon as analyzed by a carbon/sulfur analyzer is at most 100 μg per gram of gallium nitride.

In the metal nitride obtained by the production method of the present invention, inclusion of oxygen is reduced to the minimum by using a nonoxide material for the container. The amount of oxygen included in the metal nitride as an impurity can be measured by an oxygen/nitrogen analyzer, and it is usually less than 0.07 wt %, preferably less than 0.06 wt.%, particularly preferably less than 0.05 wt %.

Further, by securing sufficient supply amount and flow rate of the nitrogen source gas, the raw metal can be converted into a desired metal nitride with a high conversion, and accordingly, remaining of an unreacted raw metal can be prevented as far as possible. The remaining amount of an unreacted raw metal in the metal nitride obtained by the production method of the present invention, based on results obtained by ICP elemental analysis of the zero valent metallic element extracted from the metal nitride with an acid, is less than 5 wt %, preferably less than 2 wt %, more preferably less than 1 wt %, particularly preferably less than 0.5 wt %. Accordingly, a high purity metal nitride, i.e. a metal nitride containing a metal and nitrogen in a stoichiometric constant, can be obtained efficiently without washing with e.g. hydrochloric acid.

The metal nitride of the present invention or the metal nitride obtained by the production method of the present invention shows its intrinsic color tone as expected from the band gap since it has a low content of an unreacted raw metal (a zero valent metallic element). With reference to gallium nitride as an example, it is gallium nitride which is closer to colorless and transparent, or gallium nitride which almost looks white due to scattering, even in the form of a powder obtained by e.g. grinding. The color tone of the obtained metal nitride can be measured by a color difference meter after lo grinding into a powder. Usually, L representing the lightness is at least 60, “a” representing the red-green coordinate is at least −10 and at most 10, and “b” representing the yellow-blue coordinate is at least −20 and at most 10, and preferably L is at least 70, “a” is at least −5 and at most 5, and “b” is at least −10 and at most 5.

Application

The metal nitride of the present invention or the metal nitride obtained by the production method of the present invention is useful as a raw material for nitride bulk single crystal growth. The growth method to obtain nitride bulk single crystals may, for example, be a solution growth method using a supercritical ammonia solvent or an alkali metal flux, or a sublimation method or a melt growth method. As the case requires, it is possible to use a seed crystal or a substrate to carry out homo- or heteroepitaxial growth. The metal nitride of the present invention or the metal nitride obtained by the production method of the present invention may be washed with an acid such as hydrochloric acid or a hydrogen peroxide solution to further remove a zero valent metal and then used as a raw material. However, since the amount of a remaining unreacted raw metal is extremely small, no washing step using e.g. an acid is required, and the metal nitride can be used as a raw material for bulk nitride single crystal growth as it is.

The metal nitride of the present invention or the metal nitride obtained by the production method of the present invention may be molded into pellets or a block as the case requires. Particularly, considering its use as a raw material for nitride bulk single crystals by a solution growth method, it is suitably molded into pellets or a block, for the purpose of packing the raw material efficiently or for the purpose of controlling the dissolution rate. The pellets mean one having a curved surface at least at one portion, such as spheres or cylinders, and the block means optional one including a sheet or an agglomerate. As a means to mold the metal nitride into pellets or a block, sintering, press molding, granulation or the like may be suitably employed. In the case of molding by such a means, it is preferred that the molding is carried out in a nitrogen atmosphere or in an inert gas atmosphere, or that oxygen and moisture are removed by using an organic solvent or the like. The metal nitride of the present invention or the metal nitride obtained by the production method of the present invention, or the molded product in the form of pellets or a block obtained by molding the metal nitride, has a low concentration of impurity oxygen and stoichiometric ratio of a metal to nitrogen. Accordingly, nitride bulk single crystals to be obtained will also have a low concentration of impurity oxygen and have high quality. Further, the obtained nitride bulk single crystals may be washed with e.g. hydrochloric acid (HCl) or nitric acid (HNO₃) as the case requires and sliced parallel to a specific index plane of crystal, and further, as the case requires, subjected to etching or polishing and used as a nitride self-supporting single crystal substrate. The obtained nitride single crystal substrate contains a small amount of impurities and has high crystallinity and is thereby excellent as a substrate particularly for homoepitaxial growth, in production of various devices by means of VPE and/or MOCVD.

### EXAMPLES

Now, specific embodiments to carry out the present invention will be explained with reference to Examples. However, the present invention is by no means restricted to the following Examples within a range not to exceed the gist.

### Example 1

1.50 g of 6N metal gallium was put in a container (volume: 13 cc) made of sintered BN with a length of 100 mm, a width of 15 mm and a height of 10 mm. On this occasion, the ratio of the volume of the raw metal to the volume of the container was at most 0.05, and the ratio of the area of the bottom and wall of the container with which the raw metal was in contact to the total area of the bottom and wall of the container was at most 0.05. Further, the area of the metal gallium put in the container which could be in contact with the gas, was at least 1 cm²/g. The container was quickly placed on the center portion of a vessel comprising a horizontal cylindrical quartz tube with an inner diameter of 32 mm and a length of 700 mm, and high purity nitrogen (5N) was made to flow at a flow rate of 200 Nml/min so that the interior of the vessel and a plumbing were sufficiently replaced.

Then, while making high purity (5N) nitrogen flow at 50 Nml/min, the temperature was increased to 300° C. by an equipped heater, and nitrogen was changed to a mixed gas comprising 5N ammonia at 250 Nml/min and 5N nitrogen at 50 Nml/min. On that occasion, the volume of the ammonia gas supplied per second was at least 16 times the total volume of the raw metal, and the gas flow rate in the vicinity of a portion on the raw metal was at least 0.5 cm/s. The temperature was increased from 300° C. to 1,050° C. at 10° C./min while the gas was supplied in the same manner. On this occasion, the temperature of the outer wall at the center portion of the vessel was 1,050° C. Reaction was carried out for 3 hours while supplying the mixed gas in the same manner. After the reaction at 1,050° C. for 3 hours, the heater was switched off and the vessel was air-cooled. Cooling to 300° C. took about 4 hours. After the temperature was lowered to 300° C. or lower, the gas was changed to 5N nitrogen alone (flow lo rate: 100 Nml/min). After cooling to room temperature, the quartz tube was opened, and the container was taken out into an inert gas box at an oxygen concentration of at most 5 ppm and a moisture concentration of at most 5 ppm, followed by sufficient grinding to a size of at most 100 mesh. The weight of the obtained gallium nitride polycrystal powder was 1.799 g as calculated on the basis of the change in weight between before and after the reaction including the weight of the container, and the conversion was at least 99% as calculated on the basis of the theoretical value of the weight increase in a case where all metal gallium put is converted into gallium nitride. Further, the weight of the gallium nitride powder recovered from the container was 1.797 g, the recovery was at least 990, and the yield of gallium nitride was at least 98%.

The contents of nitrogen and oxygen of the obtained gallium nitride polycrystal powder were measured by an oxygen/nitrogen analyzer (model TC436 manufactured by LECO Corporation) and as a result, the nitrogen content was at least 16.6 wt % (at least 49.5 atomic %), and the oxygen content was less than 0.05 wt %. Further, the content of an unreacted raw gallium metal remaining in the gallium nitride polycrystal powder was quantitatively analyzed after dissolution and extraction with 20% nitric acid, and the extract from the powder was measured by an ICP elemental analyzer and as a result, it was less than 0.5 wt %.

The X-ray powder diffraction for the gallium nitride polycrystal powder was measured by using about 0.3 g of a sufficiently ground gallium nitride polycrystal powder as follows. By means of a diffraction meter (PANalytical PW1700), using CuKα ray, X-rays were emitted under conditions of 40 kV and 30 mA, and measurement was carried out under conditions of continuous measurement mode, scanning rate of 3.0°/min, read width of 0.05°, slit width DS=1°, SS=1° and RS=0.2 mm and as a result, diffraction lines of hexagonal gallium nitride (h-GaN) alone were observed, and diffraction lines of other compounds were not observed. The half width (2θ) of the diffraction line (2θ=about 37°) of (101) of h-GaN was less than 0.17°. The surface area of the gallium nitride crystal powder was measured by means of a single point BET surface area measuring method using AMS-1000 manufactured by OHKURA RIKEN CO., LTD. After deaeration at 200° C. for 15 minutes as pre-treatment, the specific surface area was obtained by the amount of nitrogen adsorbed at a liquid nitrogen temperature and as a result, it was at most 0.5 m²/g. Further, the color tone of a gallium nitride polycrystal powder obtained by the same method was measured by means of a color difference meter ZE-2000 (white reference plate Y=95.03, X=95.03 and Z=112.02) manufactured by NIPPON DENSHOKU INDUSTRIES CO., LTD as follows. About 2 cc of the gallium nitride polycrystal powder ground to at most 100 mesh was put on the bottom of a transparent round cell of 35 mm in diameter as an accessory of the color difference meter and pressed from above so that the powder was packed with no void. The cell was put on a table for powder/paste sample and a cap was put on the cell, and reflection measurement was carried out on the sample area of 30 mm in diameter and as a result, L=65, a=−0.5 and b=5.

### Example 2

4.00 g of 6N metal gallium was put in a pBN tubular container (volume: 70 cc) with a length of 100 mm and a diameter of 30 mm. On this occasion, the ratio of the volume of the raw metal to the volume of the container was at most 0.02, and the ratio of the area of the bottom and wall of the container with which the raw metal was in contact to the total area of the bottom and wall of the container was at most 0.02. Further, the area of the metal gallium put in the container which could be in contact with the gas was at least 0.7 cm²/g. Then, the same operation as in Example 1 was carried out except that the mixed gas was made to flow at a flow rate of 5N ammonia of 500 Nml/min and 5N nitrogen of 50 Nml/min, that the volume of the ammonia gas supplied per second was at least 12 times the total volume of the raw metal, and that the gas flow rate in the vicinity of a portion on the raw metal was at least 1 cm/s, to obtain a gallium nitride polycrystal powder ground to a size of at most 100 mesh. The weight of the obtained gallium nitride polycrystal powder was 4.798 g as calculated on the basis of the change in weight between before and after the reaction including the weight of the container, and the conversion was at least 99% as calculated on the basis of the theoretical value of the weight increase in a case where all metal gallium put is converted into gallium nitride. Further, the weight of the gallium nitride powder recovered from the container was 4.796 g, the recovery was at least 99%, and the yield of gallium nitride was at least 98%.

The contents of nitrogen and oxygen in the obtained gallium nitride polycrystal powder were measured by an oxygen/nitrogen analyzer (model TC436 manufactured by LECO Corporation) and as a result, the nitrogen content was at least 16.6 wt % (at least 49.5 atomic %) and the oxygen content was less than 0.05 wt %. Further, the content of an unreacted raw gallium metal remaining in the gallium nitride polycrystal powder was quantitatively analyzed in the same manner as in Example 1 and as a result, it was less than 0.5 wt %. For the gallium nitride polycrystal powder obtained, the X-ray powder diffraction was measured under the same conditions as in

Example 1 and as result, diffraction lines of hexagonal gallium nitride (h-GaN) alone were observed, and no diffraction lines of other compounds were observed. The half width (2θ) of the diffraction line (2θ=about 37°) of (101) of h-GaN was less than 0.17°. The specific surface area of the gallium nitride polycrystal powder was measured in the same manner as in Example 1 and as a result, it was at most 0.5 m²/g. Further, the color tone was measured in the same manner as in Example 1 and as a result, L=70, a=−0.4 and b=7.

### Example 3

2.00 g of 6N metal gallium was put in a graphite container (volume: 12 cc) with a length of 100 mm, a width of 18 mm and a height of 10 mm. On this occasion, the ratio of the volume of the raw metal to the volume of the container was at most 0.03, and the ratio of the area of the bottom and wall of the container with which the raw metal was in contact to the total area of the bottom and wall of the container was at most 0.03. Further, the area of the metal gallium put in the container which could be in contact with the gas was at least 0.9 cm²/g. Then, the same operation as in Example 1 was carried out except that the mixed gas was made to flow at a flow rate of 5N ammonia of 500 Nml/min and 5N nitrogen of 50 Nml/min, that the volume of the ammonia gas supplied per second was at least 25 times the total volume of the raw metal, and that the gas flow rate in the vicinity of a portion on the raw metal was at least 1 cm/s, to obtain a gallium nitride polycrystal powder ground to a size of at most 100 mesh. The weight of the obtained gallium nitride polycrystal powder was 2.398 g as calculated on the basis of the change in weight between before and after the reaction including the weight of the container, and the conversion was at least 99% as calculated on the basis of the theoretical value of the weight increase in a case where all metal gallium put is converted into is gallium nitride. Further, the weight of the gallium nitride powder recovered from the container was 2.396 g, the recovery was at least 99%, and the yield of gallium nitride was at least 98%.

The contents of nitrogen and oxygen in the obtained gallium nitride polycrystal powder were measured by an oxygen/nitrogen analyzer (model TC436 manufactured by LECO Corporation) and as a result, the nitrogen content was at least 16.6 wt % (at least 49.5 atomic %) and the oxygen content was less than 0.05 wt %. Further, the content of an unreacted raw gallium metal remaining in the gallium nitride polycrystal powder was quantitatively analyzed in the same manner as in Example 1 and as a result, it was less than 0.5 wt %. For the gallium nitride polycrystal powder obtained, and the X-ray powder diffraction was measured under the same conditions as in Example 1 and as result, diffraction lines of hexagonal gallium nitride (h-GaN) alone were observed, and no diffraction lines of other compounds were observed. The half width (2θ) of the diffraction line (2θ=about 37° of (101) of h-GaN was less than 0.17°. The specific surface area of the gallium nitride polycrystal powder was measured in the same manner as in Example 1 and as a result, it was at most 0.5 m²/g. Further, the color tone was measured in the same manner as in Example 1 and as a result, L=75, a=−0.5 and b=5.

### Example 4

A commercial carbon paper was overlayed on a quartz container (volume: 15 cc) with a length of 100 mm, a width of 18 mm and a height of 10 mm, and 2.00 g of 6N metal gallium was put on the carbon paper. On this occasion, the ratio of the volume of the raw metal to the volume of the container was at most 0.05, and the ratio of the area of the bottom and wall of the container with which the raw metal was in contact to the total area of the bottom and wall of the container was at most 0.05. Further, on this occasion, the area of the metal gallium put in the container which could be in contact with the gas was at least 0.9 cm²/g. Then, the same operation as in Example 1 was carried out except that the mixed gas was made to flow at a flow rate of 5N ammonia of 500 Nml/min and 5N nitrogen of 50 Nml/min, that the volume of the ammonia gas supplied per second was at least 25 times the total volume of the raw metal, that the gas flow rate in the vicinity of a portion on the raw metal was at least 1 cm/s, and that after the temperature was increased from 300° C. to 1,050° C. at 10° C./min, reaction was carried out at 1,050° C. for 30 minutes while the mixed gas was supplied in the same flow rate, then, the temperature was lowered to 900° C. over a period of 30 minutes, reaction was carried out at 900° C. for 2 hours, and then the heater was switched off and the vessel was air-cooled to 300° C. over a period of 3 hours, to obtain a gallium nitride polycrystal powder ground to a size of at most is 100 mesh. The weight of the obtained gallium nitride polycrystal powder was 2.399 g as calculated on the basis of the change in weight between before and after the reaction including the weight of the container, and the conversion was at least 99% as calculated on the basis of the theoretical value of the weight increase in a case where all metal gallium put was converted into gallium nitride. Further, the weight of the gallium nitride powder recovered from the container was 2.397 g, the recovery was at least 99%, and the yield of gallium nitride was at least 98%.

The contents of nitrogen and oxygen of the obtained gallium nitride polycrystal powder were measured by an oxygen/nitrogen analyzer (model TC436 manufactured by LECO Corporation) and as a result, the nitrogen content was at least 16.6 wt % (at least 49.5 atomic %) and the oxygen content was less than 0.05 wt %. Further, the s content of an unreacted raw gallium metal remaining in the gallium nitride polycrystal powder was quantitatively analyzed in the same manner as in Example 1 and as a result, it was less than 0.5 wt %. The X-ray powder diffraction for the gallium nitride polycrystal powder obtained was measured under the same conditions as in Example 1 and as a result, diffraction lines of hexagonal gallium nitride (h-GaN) alone were observed, and no diffraction lines of other compounds were observed. The half width (2θ) of the diffraction line (2θ=about 37°) of is (101) of h-GaN was less than 0.17°. The specific surface area of the gallium nitride polycrystal powder was measured in the same manner as in Example 1 and as a result, it was at most 0.5 m²/g. Further, the color tone was measured in the same manner as in Example 1 and as a result, L=75, a=−0.5 and b=6.

### Comparative Example 1

In order to demonstrate the effects by use of a nonoxide material for the container, the nitridation was carried out in the same manner as in Example 3 except that an alumina container (volume: 12 cc) was used. Gallium metal reacted with the alumina container during the nitridation or its procedure, and the formed product strongly adhered to the alumina container. The weight of the obtained gallium nitride polycrystal powder was 2.391 g as calculated on the basis of the change in weight between before and after the reaction including the weight of the container, and the conversion was less than 98% as calculated on the basis of the theoretical value of the weight increase in a case were all metal gallium put was converted into gallium nitride. Further, the weight of the gallium nitride powder recovered from the container was 2.271 g, the recovery was at most 97%, and the yield of gallium nitride was at most 95%.

The oxygen content in the obtained gallium nitride polycrystal powder was measured by means of an oxygen/nitrogen analyzer (model TC436 manufactured by LECO corporation) and as a result, it was at least 0.05 wt %. Further, the content of an unreacted raw gallium metal remaining in the gallium nitride polycrystal powder was quantitatively analyzed in the same manner as in Example 1 and as a result, it was at least 0.5 wt %. The X-ray powder diffraction for the gallium nitride polycrystal powder obtained was measured under the same conditions as in Example 1 and as a result, the crystals were hexagonal crystals, but the half width (2θ) of the diffraction line (2θ=about 37°) of (101) was 0.20° . Further, the color tone was measured in the same manner as in Example 1 and as a result, L=57, a=−0.3 and b=12.

### Comparative Example 2

In order to demonstrate the effects by use of a nonoxide material for the container, the nitridation was carried out in the same manner as in Example 4 except that metal gallium was directly put on a quartz container without carbon paper overlayed. Gallium metal reacted with the quartz container during the nitridation or its procedure, and the formed product strongly adhered to the alumina container. The weight of the obtained gallium nitride crystal powder was 2.392 g as calculated on the lo basis of the change in weight before and after the reaction including the weight of the container, and the conversion was at most 98% as calculated on the basis of the theoretical value of the weight increase in a case where all metal gallium put was converted into gallium nitride. Further, the weight of the gallium nitride powder recovered from the container was 2.296 g, the recovery was at most 97%, and the yield of gallium nitride was at most 95%.

The oxygen content in the obtained gallium nitride polycrystal powder was measured by an oxygen/nitrogen analyzer (model TC436 manufactured by LECO Corporation) and as a result, it was at least 0.05 wt %. Further, the content of an unreacted raw gallium metal remaining in the gallium nitride polycrystal powder was quantitatively analyzed in the same manner as in Example 1 and as a result, it was at least 0.5 wt %. The X-ray powder diffraction for the gallium nitride polycrystal powder obtained was measured under the same conditions as in Example 1 and as a result, the crystals were hexagonal crystals, but the half width (2θ) of the diffraction line (2θ=about 37°) of (101) was 0.20°. Further, the color s tone was measured in the same manner as in Example 1 and as a result, L=55, a=−0.4 and b=3.

### Comparative Example 3

In order to demonstrate the effects of the supply amount and the flow rate of ammonia, the nitridation was carried out in the same manner as in Example 3 except that the flow rate of ammonia was 25 Nml/min. On that occasion, the volume of the ammonia gas supplied per second was 1.25 times the total volume of the raw metal, and the gas flow rate in the vicinity of a portion on the is raw metal was 0.05 cm/s. After the reaction, a product containing an unreacted raw gallium metal as a metallic gallium significantly escaped from the container, the product adhered also to the wall of the vessel and was hardly recovered. The weight of the recovered powder was 2.240 g, and the yield of the obtained powder was at most 95% based on the weight obtained assuming that 100% of the powder was converted into gallium nitride.

The obtained gallium nitride polycrystal powder was partially blackish. The content of an unreacted raw gallium metal remaining was quantitatively analyzed in the same manner as in Example 1 and as a result, it was 1 wt % or more. The X-ray powder diffraction for the gallium nitride polycrystal powder obtained was measured under the same conditions as in Example 1 and as a result, the crystals were hexagonal crystals, but the half width (2θ) of the diffraction line (2θ=about 37°) of (101) was 0.20°. Further, the color tone was measured in the same manner as in Example 1 and as a result, L=53, a=−0.4 and b=3.

### Comparative Example 4

In order to examine influences of the volume ratio lo of the raw metal to the container and the ratio of the area of the raw metal in contact with the container to the area of the interior of the container on the yield of the powder and the like, the nitridation was carried out in the same manner as in Example 2 except that a pBN crucible having an inner diameter of 12 mm and a volume of 1.7 cc was used as the container. The ratio of the volume of the raw metal to the volume of the container was 0.39, and the ratio of the area of the bottom and wall of the container with which the raw metal was in contact to the total area of the bottom and wall of the container was at least 0.3. The area of metal gallium put in the container which could be in contact with the gas was 0.45 cm²/g. After the reaction, the product containing an unreacted raw gallium metal as a metallic gallium significantly escaped from the container and was hardly recovered. The weight of the recovered powder was 2.263 g, and the yield of the powder was at most 95% based on the weight obtained assuming that 100% of the powder was converted into gallium nitride.

The obtained gallium nitride polycrystal powder was partially blackish. The content of an unreacted raw gallium metal remaining was quantitatively analyzed in the same manner as in Example 1 and as a result, it was 1 wt % or more. The X-ray powder diffraction for the gallium nitride polycrystal powder obtained was measured under the same conditions as in Example 1 and as a result, the crystals were hexagonal, but the half width (2θ) of the diffraction line (2θ=about 37°) of (101) was 0.22°. Further, the color tone was measured in the same manner as in Example 1 and as a result, L=50, a=−0.4 and b=3.

### Comparative Example 5

As commercial gallium nitride reagent samples, gallium nitride supplied by Sigma-Aldrich (catalog number 07804121, hereinafter abbreviated as company A) and gallium nitride supplied by Wako Pure Chemical Industries, Ltd. (catalog number 481769, hereinafter abbreviated as company W) were used. The contents of nitrogen and oxygen were measured by an oxygen/nitrogen analyzer (model TC436, manufactured by LECO Corporation) and as a result, gallium nitride supplied by company A had a nitrogen content of 14.0 wt % (at most 40.3 atomic %) and an oxygen content of 5.2 wt %. Further, gallium nitride supplied by company W had a nitrogen content of 15.3 wt % (at most 46.9 atomic %) and an oxygen content of 0.48 wt %. With respect to gallium nitride supplied by company W, the content of a gallium metal remaining was quantitatively analyzed by dissolution and extraction with heated nitric acid and subjecting the extract to an ICP elemental analyzer and as a result, it was 10 wt %.

The X-ray powder diffraction was carried out under the same conditions as in Example 1 and as a result, the crystals were hexagonal with respect to both gallium nitrides of companies A and W, but with respect to gallium nitride of company W, diffraction lines of gallium metal were observed in addition to hexagonal gallium nitride. On the contrary, with respect to gallium nitride of company A, no other diffraction lines were observed, but the half width (2θ) of the diffraction line (2θ=about 37°) of (101) of h-GaN was at least 0.5°. Further, the specific surface area of gallium nitride of company A was measured in the same manner as in Example 1 and as a result, it was at least 2 m²/g. Further, the color tones of gallium nitrides of companies A and W were measured in the same manner as in Example 1 and as a result, L=80, a=−3 and b=25 with respect to h-GaN of company A, and L=50, a=−0.4 and b=3 with respect to h-GaN of company W.

As evident from the results of the above Examples and Comparative Examples, the metal nitrides of Examples obtained by the production method of the present invention have higher crystallinity and contain a smaller amount of impurity oxygen and an unreacted raw metal, have high quality and are excellent in color tone, as compared with ones obtained by methods of Comparative Examples.

Industrial Applicability

The present invention relates to a method for producing a metal nitride by nitridation of a metal, particularly, it relates to a method for efficiently producing high purity and highly crystalline polycrystals of a nitride of a metal element of Group 13 of the Periodic Table as represented by gallium nitride, and a metal nitride obtained by the production method. The present invention provides a metal nitride containing a lo small amount of impurities and containing a metal and nitrogen in a ratio closer to a stoichiometric constant, as a raw material for producing bulk crystals to be used as a substrate for homoepitaxial growth applicable to production of an electron device such as a light emitting diode or a laser diode comprising a compound semiconductor of Group III - V of the Periodic Table, as represented by gallium nitride. Bulk crystals produced by using it as a raw material are less likely to have problems such as dislocation and defects and have excellent quality and are thereby industrially highly applicable.

The entire disclosure of Japanese Patent Application No. 2004-240344 filed on Aug. 20, 2004 including specification, claims, and summary is incorporated herein by reference in its entirety.

1. A metal nitride containing a metal element of Group 13 of the Periodic Table, characterized by the metal nitride having an oxygen content of less than 0.07 wt % and a specific surface area of at most 0.5 m²/g.

2. The metal nitride according to claim 1, which has a content of a zero valent metal element of less than 5 wt %.

3. The metal nitride according to claim 1, which contains nitrogen in an amount of at least 47 atomic %.

4. The metal nitride according to claim 1, which has a color tone, wherein the color tone measured by a color difference meter is such that L is at least 60, “a” is at least −10 and at most 10, and “b” is at least −20 and at most 10.

5. The metal nitride according to claim 1, which has a maximum length of primary particles in a major axis direction of at least 0.05 μm and at most 1 mm.

6. The metal nitride according to claim 1, wherein the metal element of Group 13 of the Periodic Table is gallium.

7. A metal nitride molded product, which is pellets or a block obtained by molding the metal nitride as defined in claim 1.

8. A method for producing metal nitride bulk crystals, comprising forming crystals of the metal nitride as defined in claim 1.

9. The method for producing metal nitride bulk crystals according to claim 8, wherein the metal nitride has a half width of a peak in power X-ray diffraction of at most 0.2°.

10. The method for producing metal nitride bulk crystals according to claim 8, wherein a content of a zero valent metal element in the metal nitride is less than 5 wt %.

11. The method for producing metal nitride bulk crystals according to claim 8, wherein the metal nitride bulk crystals are obtained by a solution growth method.

12. A method for producing metal nitride bulk crystals, comprising forming crystals of the metal nitride molded product as defined in claim 7.

13. The method for producing metal nitride bulk crystals according to claim 12, wherein the metal nitride molded product has a half width of a peak in power X-ray diffraction of at most 0.2°.

14. The method for producing metal nitride bulk crystals according to claim 12, wherein a content of a zero valent metal element in the metal nitride is less than 5 wt %.

15. The method for producing metal nitride bulk crystals according to claim 12, wherein the metal nitride bulk crystals are obtained by a solution growth method.
